(19) United States
(12) Patent Application Publication
(10) Pub. No.: US 2025/0267984 A1
(43) Pub. Date: Aug. 21, 2025

(54) SEMICONDUCTOR LIGHT-EMITTING DEVICE AND LIGHT-EMITTING APPARATUS HAVING THE SAME

(71) Applicant: XIAMEN SAN'AN OPTOELECTRONICS CO., LTD., Xiamen (CN)

(72) Inventors: TUNGWEI YEN, Xiamen (CN); Yanchun CHEN, Xiamen (CN); Chien-Yao TSENG, Xiamen (CN); CHI-LUN CHOU, Xiamen (CN); Shaohua HUANG, Xiamen (CN); Chi-Ming TSAI, Xiamen (CN); CHUNG-YING CHANG, Xiamen (CN)

(21) Appl. No.: 19/196,959

(22) Filed: May 2, 2025

Related U.S. Application Data
(63) Continuation-in-part of application No. PCT/CN2022/141499, filed on Dec. 23, 2022.

(51) Int. Cl. H10H 20/81; H10H 20/812; H10H 20/816

(52) U.S. Cl. CPC H10H 20/8215; H10H 20/812; H10H 20/8162

(57) ABSTRACT

A semiconductor light-emitting device includes an n-type semiconductor layer, a light-emitting structure, a first electron blocking layer, a second electron blocking layer, and a p-type hole injection layer, which are sequentially stacked in such order. The light-emitting structure includes well layers and barrier layers which are stacked alternately. The first electron blocking layer contacts a last one of the barrier layers of the light-emitting structure and has an energy band gap (E_{g3}) that is larger than an energy band gap (E_{g4}) of the second electron blocking layer. The energy band gap (E_{g4}) of the second electron blocking layer is larger than an energy band gap (E_{g2}) of the barrier layers, and an energy band gap (E_{g5}) of the p-type hole injection layer is smaller than the energy band gap (E_{g2}) of the barrier layers.

### CROSS-REFERENCE TO RELATED APPLICATION

This application is a continuation-in-part (CIP) of International Application No. PCT/CN2022/141499, filed on Dec. 23, 2022, the entire disclosure of which is incorporated by reference herein.

### FIELD

The disclosure relates to a semiconductor light-emitting device, and more particularly to a semiconductor light-emitting device and a light-emitting apparatus having the same.

### BACKGROUND

A semiconductor light-emitting device is an inorganic semiconductor device, which emits light through the combination of electrons and holes. An ultraviolet (UV) light-emitting device emits UV light and is widely used in a variety of fields, e.g. curing the polymeric material, sterilization of medical equipment, a light source for generating white light, etc.

Optoelectronic performance of a conventional UV light-emitting device is directly related to characteristics of a light-emitting structure therein (e.g., quality of a quantum well, a doping concentration, an interface defect, a V-shaped groove, etc.). For example, a p-type dopant (e.g. magnesium) tends to diffuse into the quantum well under heat, thereby forming a deep level defect, which may impact relative luminance of the conventional UV light-emitting device in the aging process.

### SUMMARY

Therefore, an object of the disclosure is to provide a semiconductor light-emitting device and a light-emitting apparatus having the same that can alleviate at least one of the drawbacks of the prior art.

According to one aspect of the disclosure, a semiconductor light-emitting device includes an n-type semiconductor layer, a light-emitting structure, a first electron blocking layer, a second electron blocking layer, and a p-type hole injection layer, which are sequentially stacked in such order. The light-emitting structure includes well layers and barrier layers, which are stacked alternately. The first electron blocking layer contacts a last one of the barrier layers of the light-emitting structure and has an energy band gap (E_{g3}) that is larger than an energy band gap (E_{g4}) of the second electron blocking layer. The energy band gap (E_{g4}) of the second electron blocking layer is larger than an energy band gap (E_{g2}) of each of the barrier layers, and an energy band gap (E_{g5}) of the p-type hole injection layer is smaller than the energy band gap (E_{g2}) of each of the barrier layers.

According to another aspect of the disclosure, a semiconductor light-emitting device includes a n-type semiconductor layer, a light-emitting structure, an electron blocking layer, and the p-type hole injection layer, which are stacked sequentially in such order. The light-emitting structure includes well layers and barrier layers which are alternatively stacked. An energy band gap of the electron blocking layer is larger than an energy band gap (E_{g2}) of each of the barrier layers. The electron blocking layer has at least one V-shaped groove that extends into the light-emitting structure, and the p-type hole injection layer fills the at least one V-shaped groove. The p-type hole injection layer has an energy band gap (E_{g5}) that is smaller than the energy band gap (E_{g2}) of the barrier layers.

According to yet another aspect of the disclosure, a light-emitting apparatus includes any one of the aforesaid semiconductor light-emitting devices.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view of an epitaxial laminate of an embodiment of a semiconductor light-emitting device according to the present disclosure.

FIG. 2 is a schematic view of a light-emitting structure of an embodiment of a semiconductor light-emitting device according to the present disclosure.

FIG. 3 is a schematic view of an epitaxial laminate of an embodiment of a semiconductor light-emitting device according to the present disclosure.

FIG. 4 is a schematic view of a light-emitting structure of an embodiment of a semiconductor light-emitting device according to the present disclosure.

FIG. 5 is fragmentary view illustrating energy band gaps of the epitaxial laminate shown in FIG. 3.

FIG. 6 is a transmission electron microscope (TEM) image of the epitaxial laminate shown in FIG. 3.

FIG. 7 is a schematic view of a light-emitting structure of an embodiment of a semiconductor light-emitting device according to the present disclosure.

FIG. 8 is a schematic view of a light-emitting structure of an embodiment of a semiconductor light-emitting device according to the present disclosure.

FIG. 9 is an energy-dispersive x-ray spectroscopy (EDX) spectrum of a light-emitting structure of an embodiment of a semiconductor light-emitting device according to the present disclosure.

FIG. 10 is a fragmentary view illustrating energy band gaps of the epitaxial laminate shown in FIG. 8.

FIG. 11 is a schematic view of an embodiment of a semiconductor light-emitting device according to the present disclosure.

FIG. 12 shows scatter plots of light output power (LOP) versus wavelength of Sample 1 and Sample 2.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Composition and a dopant of each layer included in a semiconductor light-emitting device of the present disclosure may be analyzed by any proper instrument, such as secondary ion mass spectrometer (SIMS). A thickness of each layer included in the semiconductor light-emitting device of the present disclosure may be analyzed by any proper instrument, such as a transmission electron microscope (TEM), or a scanning electron microscope (SEM), which may be used with the SIMS.

Through SIMS or energy-dispersive x-ray spectroscopy (EDX) cooperating with TEM a ratio of contents of Group III elements (aluminum, indium, gallium, etc.) included in the semiconductor light-emitting device may be obtained. In addition, through the contents of aluminum and indium, an energy band gap may be predicted. If the aluminum content is larger than the indium content, the energy band gap is higher; if the indium content is larger than the aluminum content, the energy band gap is lower.

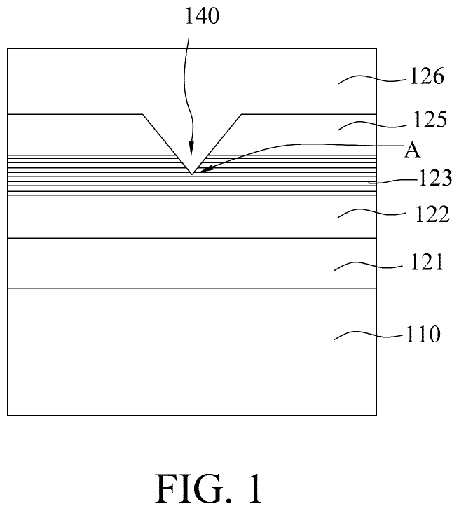

An embodiment of a light-emitting device of the present disclosure is a gallium nitride-based (GaN-based) semiconductor light-emitting device, but is not limited thereto. In some embodiments, the GaN-based semiconductor light-emitting device may have a lateral configuration, a vertical configuration, a flip-chip configuration, etc. FIG. 1 shows a schematic view of an epitaxial laminate of an embodiment of a semiconductor light-emitting device according to this disclosure. The epitaxial laminate of the semiconductor light-emitting device includes an n-type semiconductor layer 121, a supper lattice layer 122, a light-emitting structure 123, an electron blocking layer 125, and a p-type hole injection layer 126, which are stacked sequentially from bottom to top in such order. The epitaxial laminate may be formed through a metal-organic chemical vapor deposition (MOCVD) method, a chemical vapor deposition (CVD) method, a plasma enhanced chemical vapor deposition method (PECVD) method, a molecular beam epitaxy (MBE) method, a hydride vapor phase epitaxy (HVPE) method, etc., but is not limited thereto. In addition, the semiconductor light-emitting device may include a substrate 110 for growing or supporting the abovementioned layers.

In some embodiments, the epitaxial laminate may be an AlGaInN-based semiconductor material. The n-type semiconductor layer 121 is configured for providing electrons to the light-emitting structure 123, and is made of a semiconductor material having a chemical formula of Inₓ₁Al_{y1}Ga_{1-x1-y1}N, where 0≤x1≤1, 0≤y1≤1, 0≤x1+y1≤1, such as GaN, AlN, AlGaN, InGaN, InN, InAlGaN, AlInN, etc; an n-type dopant may be doped therein, such as Si, Ge, Sn, Se, Te, etc. In some embodiments where the semiconductor light-emitting device is an UV LED (light-emitting diode), the n-type semiconductor layer 121 may include AlGaN.

The supper lattice layer 122 is located between the n-type semiconductor layer 121 and the light-emitting structure 123, and may have functions of adjusting stress and current spreading. The supper lattice layer 122 includes periodic units. Each of the periodic units includes at least two thin layers that are made of different materials. The different materials may be nitride-based semiconductor materials. In an embodiment, the supper lattice layer 122 includes periodic units each of which is AlGaN/GaN. In an embodiment, at least one of the periodic units includes a layered structure having a first sub-layer, a second sub-layer, and a third sub-layer, and may be InGaN/AlGaN/AlN, GaN/AlGaN/AlN or InGaN/GaN/AlN. The periodic units having a large energy band gap may regulate radiative recombination, thereby increasing recombination efficiency of the light-emitting structure 123 so as to improve luminance of the semiconductor light-emitting device. In addition, leakage, which is caused by holes or electrons obtaining additional energy under a high temperature, may be avoided, thereby improving luminance stability of the semiconductor light-emitting device at a high temperature with a hot/cold (H/C) factor being greater than 70%.

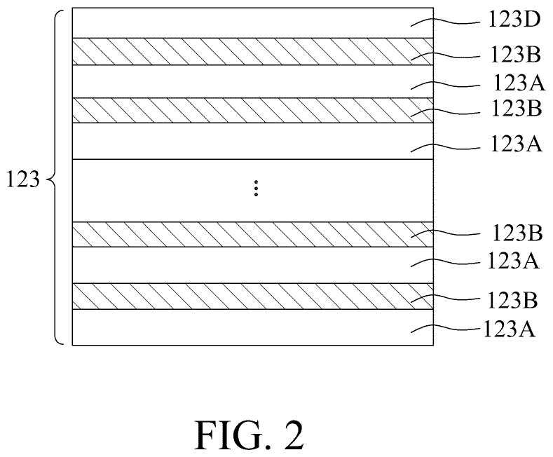

The light-emitting structure 123 is formed on the supper lattice layer 122. The light-emitting structure 123 may be a single quantum well structure, one or more multiple quantum well structures, a quantum wire structure, a quantum dot structure, etc., and may be made of a Group III-V semiconductor material. In some embodiments, the light-emitting structure 123 may have a quantum well structure and be made of a material with a chemical formula of Inₓ₂Al_{y2}Ga_{1-x2-y2}N, where 0≤x2≤1, 0≤y2≤1, 0≤x2+y2≤1. The light-emitting structure 123 may have one or more multiple quantum well structures and include barrier layers 123A, 123D and well layers 123B that are arranged between the barrier layers 123A, 123D. In some embodiments, the well layers 123B and the barrier layers 123A, 123D may be stacked alternatively, as illustrated in FIG. 2. The number of the well layers 123B and the number of the barrier layers 123A, 123D each may range from 3 to 8. Each of the well layers 123B may be made of a material that has an energy band gap smaller than that of each of the barrier layers 123A, 123D; that is, an energy band gap (E_{g1}) of each of the well layers 123B is smaller than an energy band gap (E_{g2}) of each of the barrier layers 123A, 123D. With an increase in an Al content of the well layers 123B, the energy band gap and a lattice constant of the well layers 123B increase. Therefore, light-emitting efficiency of the semiconductor light-emitting device would be improved and an emission wavelength of light emitted by the semiconductor light-emitting device would be reduced. In an embodiment, one of the well layers 123B (i.e., the last one well layer) that is nearest to the p-type hole injection layer 126 in the light-emitting structure 123 has a p-type doping concentration equal to or smaller than 5×10¹⁷ atoms/cm³, and the remaining well layers 123B each have a p-type doping concentration equal to or smaller than 1×10¹⁷ atoms/cm³. Controlling the p-type doping concentration of each of the well layers 123B in the light-emitting structure 123, especially the p-type doping concentration of the last one well layer 123B, is beneficial to improve an anti-aging capability of the semiconductor light-emitting device. If the p-type doping concentration of the last one well layer 123B is larger than 1×10¹⁸ atoms/cm³, long-term lumen depreciation of the semiconductor light-emitting device may occur early; in particular, severe lumen depreciation may occur in a large current condition.

The emission wavelength of the light emitted by the semiconductor light-emitting device may be determined by composition and a thickness of the light-emitting structure 123. In some embodiments, a ratio of a thickness of each of the well layers 123B to a thickness of each of the barrier layers 123A ranges from 1:1.7 to 1:2. Therefore, the light emitted by the semiconductor light-emitting device has the emission wavelength ranging from 340 nm to 425 nm (i.e., UV light), and internal quantum efficiency of the semiconductor light-emitting device may be enhanced.

In some embodiments, the light-emitting structure 123 has a last one of the barrier layers 123D (i.e., the last one barrier layer) that is adjacent to the electron blocking layer 125. The last barrier layer 123D has a thickness ranging from 3 nm to 40 nm. If the thickness of the last one barrier layer 123D is smaller than 3 nm, current leakage may occur. The last barrier layer 123D may include a material with a chemical formula of InⱼAlₖGa₍₁₋ⱼ₋ₖ₎N, where 0≤j≤1, 0≤k≤1. In an embodiment, the last barrier layer 123D and one of the remaining barrier layers 123A have the same material. In some embodiments, the last barrier layer 123D has a thickness smaller than that of one of the remaining barrier layers 123A. In some embodiments, the thickness of the last one barrier layer 123D is smaller than the thickness of each of the remaining barrier layers 123A. In an embodiment, the last barrier layer 123D has a p-type doping concentration that is equal to or smaller than 1×10¹⁸ atoms/cm³. Except for the last barrier layer 123D, the barrier layers 123A (i.e., the remaining barrier layers 123A) each have a p-type doping concentration that is equal to or smaller than 1×10¹⁷ atoms/cm³. In certain embodiments, the last barrier layer 123D has the p-type doping concentration that is equal to or smaller than 5×10¹⁷ atoms/cm³. Controlling the p-type doping concentration of each of the barrier layers 123A, 123D in the light-emitting structure 123, especially the p-type doping concentration of the last barrier layer 123D, is beneficial to improve the anti-aging capability of the semiconductor light-emitting device.

The electron blocking layer 125 is located between the light-emitting structure 123 and the p-type hole injection layer 126, and includes a semiconductor material represented by In_{z}Al_{w}Ga_{1-z-w}, where 0≤z≤1, 0≤w≤1, 0≤z+w≤1, and has a lattice constant greater than that of the p-type hole injection layer 126. In some embodiments where the semiconductor light-emitting device is a UV LED, the electron blocking layer 125 includes AlGaN. The electron blocking layer 125 may have an energy band gap that is larger than an energy band gap of the light-emitting structure 123. When high current is applied to the semiconductor light-emitting device, the electron blocking layer 125 may prevent electrons, which are injected into the light-emitting structure 123 from the n-type semiconductor layer 121, from further flowing into the p-type hole injection layer 126. Therefore, a probability of recombination of electrons and holes in the light-emitting structure 123 may increase, thereby preventing current leakage.

In some embodiments, the electron blocking layer 125 includes the semiconductor material represented by In_{z}Al_{w}Ga_{1-z-w}N, where 0≤z≤0.05, 0<w≤1. In certain embodiments, the electron blocking layer 125 has a p-type doping concentration that is equal to or smaller than 5×10¹⁹ atoms/cm³. In certain embodiments, the p-type doping concentration of the electron blocking layer 125 ranges from 5×10¹⁷ atoms/cm³ to 2×10¹⁹ atoms/cm³. If the p-type doping concentration of the electron blocking layer 125 is smaller than 5×10¹⁷ atoms/cm³, a voltage of the semiconductor light-emitting device may increase. In certain embodiments, the p-type doping concentration of the electron blocking layer 125 ranges from 1×10¹⁸ atoms/cm³ to 2×10¹⁹ atoms/cm³; therefore, a voltage of the semiconductor light-emitting device may be better controlled, and the p-type doping quality of the light-emitting structure 123 may be better controlled, so that the semiconductor light-emitting device may have a good anti-lumen depreciation capacity.

The p-type hole injection layer 126 is formed on the electron blocking layer 125, and is made of a semiconductor compound to inject holes into the light-emitting structure 123. The p-type hole injection layer 126 is made of a semiconductor material represented by Inₓ₃Al_{y3}Ga_{1-x3-y3}N, where 0≤x2≤1, 0≤y2≤1, 0≤x2+y2≤1. The semiconductor material of the p-type hole injection layer 126 may be GaN, AlN, AlGaN, InGaN, InN, InAlGaN, AlInN, etc., and may be doped with a p-type dopant, e.g., Mg, Zn, Ca, Sr, Ba, etc. In some embodiments where the semiconductor light-emitting device is a UV LED, the p-type hole injection layer 126 may include AlGaN. In addition, a contact layer (not depicted in the drawings) may be formed on the p-type hole injection layer 126. The contact layer may be a highly doped p-type GaN layer or a highly doped p-type AlGaN layer. For example, the contact layer may be a p-type AlGaN layer having a p-type doping concentration larger than 1×10²⁰ atoms/cm³, which is beneficial to form a good ohmic contact with an electrode. In an embodiment, the p-type hole injection layer 126 has a doping concentration that is equal to or smaller than 1×10²⁰ atoms/cm³. In an embodiment, the p-type hole injection layer 126 has an energy band gap (E_{g5}), which is larger than the energy band gap (E_{g1}) of the well layers 123B. In an embodiment, the energy band gap (E_{g5}) of the p-type hole injection layer 126 is smaller than the energy band gap (E_{g2}) of the barrier layers 123A, 123D.

In an embodiment, the electron blocking layer 125 has at least one V-shaped groove 140 that extends into the light-emitting structure 123, and the p-type hole injection layer 126 fills the at least one V-shaped groove 140. Since the at least one V-shaped groove 140 extends into and is formed in the light-emitting structure 123, electrons and holes that are injected into the light-emitting structure 123 may not reach threading dislocations, which is beneficial to inhibit non-emitting recombination in the light-emitting structure 123. In addition, the at least one V-shaped groove 140 has an upper end that is located in a top surface of the electron blocking layer 125 and a lower end (A). The lower end (A) is located not lower than a lower surface of the light-emitting structure 123 (specifically, the lower end (A) is located not lower than a lower surface of a lowest one of the well layers 123B that is adjacent to the n-type semiconductor layer 121). In some embodiments, the lower end (A) is located in the light-emitting structure 123 so that a path of current leakage in the epitaxial laminate may be reduced, thereby enhancing the light-emitting efficiency. At least a part of the at least one V-shaped groove 140 is located in the light-emitting structure 123, and is filled (e.g., completely filled) by the p-type hole injection layer 126. Controlling a depth of the at least one V-shaped groove 140 is beneficial to control the p-type doping concentration of the light-emitting structure 123. In an embodiment, the upper end of the at least one V-shaped groove 140 has a maximum width that is equal to or smaller than 160 nm and the depth of the at least one V-shaped groove 140 is smaller than 120 nm, so that the p-type doping concentration of the light-emitting structure 123 may be well controlled to be smaller than 5×10¹⁷ atoms/cm³.

Generally, in the embodiment where the semiconductor light-emitting device is a UV LED, to reduce light absorption by the semiconductor layers of the UV LED, energy band gaps of the semiconductor layers are to be increased. By controlling the Al contents in the semiconductor layers, the energy band gaps of the semiconductor layers may be adjusted. However, the semiconductor layer with a high Al content is unfavorable to filling of the at least one V-shaped groove 140. In this embodiment, by controlling the energy band gap (E_{g5}) of the p-type hole injection layer 126 to be higher than the energy band gap (E_{g1}) of the well layers 123B and to be lower than the energy band gap (E_{g2}) of the barrier layers 123A, 123D, the p-type hole injection layer 126 may fill the at least one V-shaped groove 140 well, thereby reducing current leakage and improving an anti-aging capability of the semiconductor light-emitting device.

In this embodiment, forming the at least one V-shaped groove 140 in the epitaxial laminate is beneficial to increase the recombination efficiency of holes and electrons in the light-emitting structure 123. By controlling the position of the lower end (A) and the depth of the at least one V-shaped groove 140, and by adjusting the energy band gap (E_{g5}) of the p-type hole injection layer 126 to be smaller than the energy band gap (E_{g2}) of the barrier layers 123A, 123D so as to fill the at least one V-shaped groove 140 well, the p-type doping concentration of the light-emitting structure 123 may be well controlled so that the anti-aging capability of the light-emitting device may be enhanced.

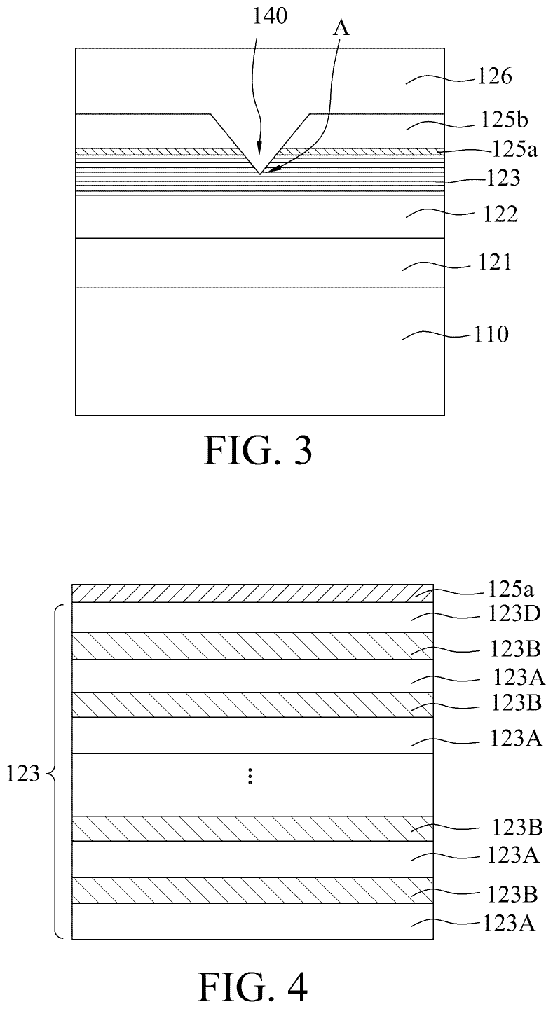

FIGS. 3 and 4 show an epitaxial laminate of another embodiment of the semiconductor light-emitting device of the present disclosure. The epitaxial laminate in this embodiment is the same as that shown in FIG. 1 except for the electron blocking layer 125. In this embodiment, the electron blocking layer 125 includes a first electron blocking layer 125a and a second electron blocking layer 125b.

As shown in FIG. 4, the first electron blocking layer 125a directly contacts the last barrier layer 123D. The first electron blocking layer 125a has an energy band gap (E_{g3}), and the second electron blocking layer 125b has an energy band gap (E_{g4}), where E_{g3}>E_{g4}. The first electron blocking layer 125a includes a material represented by Al_{g}Ga_{1-g}N, where 0.5<g≤1. In certain embodiments, g is larger than 0.7 and is equal to or smaller than 1. In an embodiment, the first electron blocking layer 125a includes AlN. In this embodiment, the first electron blocking layer 125a has a thickness ranging from 0.5 nm to 15 nm, e.g., from 0.5 nm to 10 nm. Within this range, diffusion of the p-type dopant into the light-emitting structure 123 may be alleviated. If the thickness of the first electron blocking layer 125a is smaller than 0.5 nm, there will be a decrease in the capability of blocking diffusion of the p-type dopant into the light-emitting structure 123, and the electrostatic protection capability of the semiconductor light-emitting device may be adversely affected. If the thickness of the first electron blocking layer 125a is larger than 15 nm, the electric properties of the semiconductor light-emitting device, e.g., positive voltage, current leakage, would be deteriorated. In certain embodiments, the first electron blocking layer 125a has a p-type doping concentration that is equal to or smaller than 1×10¹⁸ atoms/cm³.

In certain embodiments, the energy band gap (E_{g4}) of the second electron blocking layer 125b is larger than the energy band gap (E_{g2}) of one of the barrier layers 123A, 123D. In some embodiments, the energy band gap (E_{g4}) of the second electron blocking layer 125b is larger than the energy band gap (E_{g2}) of a first one of the barrier layers 123A that is adjacent to the supper lattice layer 122. The second electron blocking layer 125b includes a material represented by InₐAl_{b}Ga_{1-a-b}N, where 0≤a≤0.05, 0<b≤1. If b is smaller than 0.05, the electrostatic protection capability of the semiconductor light-emitting device would be deteriorated. The second electron blocking layer 125b may cooperate with the first electron blocking layer 125a to improve the light-emitting efficiency of the semiconductor light-emitting device. In certain embodiments, the second electron blocking layer 125b has a p-type doping concentration that is equal to or smaller than 5×10¹⁹ atoms/cm³, e.g., equal to or smaller than 2×10¹⁹ atoms/cm³.

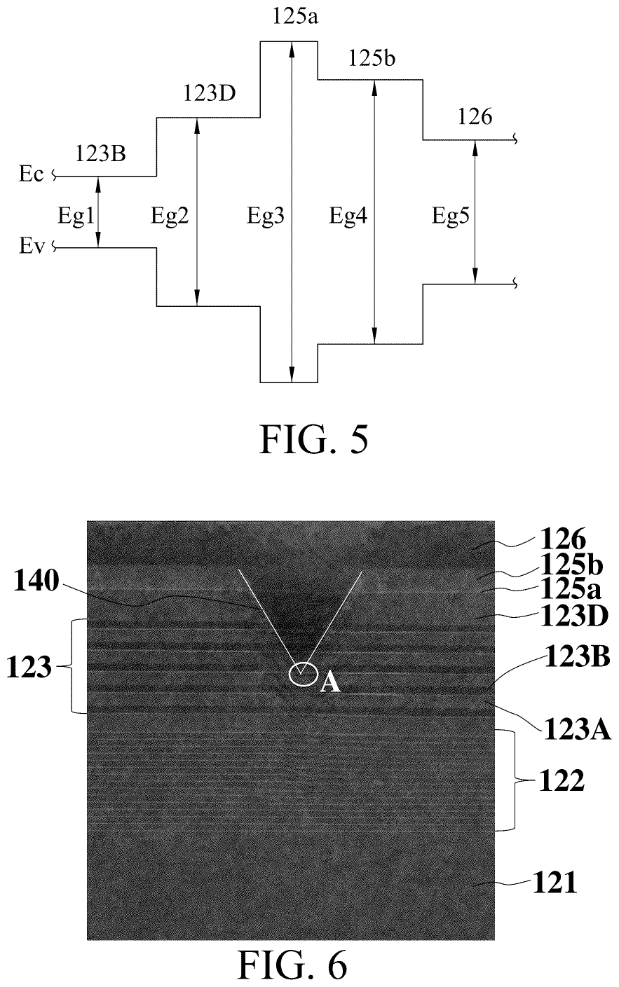

FIG. 5 shows a relationship of the energy band gaps of the light emitting structure 123, the electron blocking layer 125 and the p-type hole injection layer 126 in the epitaxial laminate shown in FIG. 3, where E_{g3}>E_{g4}>E_{g2}>E_{g5}>E_{g1}. FIG. 6 is a TEM image of the epitaxial laminate shown in FIG. 3, which includes the n-type semiconductor layer 121, the supper lattice layer 122, the light-emitting structure 123, the first electron blocking layer 125a, the second electron blocking layer 125b, and the p-type hole injection layer 126 from bottom to top. The at least one V-shaped groove 140 in the first electron blocking layer 125a and the second electron blocking layer 125b extends into the light-emitting structure 123, and the p-type hole injection layer 126 fills the at least one V-shaped groove 140. The lower end (A) of the at least one V-shaped groove 140 is located in the middle of the light-emitting structure 123. In this embodiment, through controlling the energy band gap (E_{g5}) of the p-type hole injection layer 126 to be smaller than the energy band gap (E_{g2}) of the barrier layers 123A, 123D, the p-type hole injection layer 126 may fill the at least one V-shaped groove 140 well, thereby reducing current leakage of the semiconductor light-emitting device. Moreover, the first electron blocking layer 125a and the second electron blocking layer 125b may restrict the p-type doping concentration in the light-emitting structure 123, which may improve the light-emitting efficiency and the anti-aging capability of the semiconductor light-emitting device.

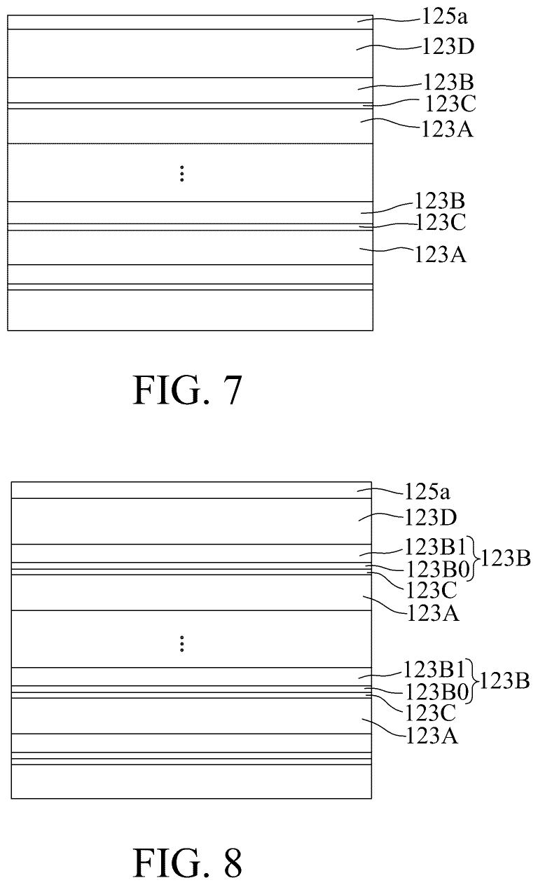

FIG. 7 shows an epitaxial laminate of yet another embodiment of the semiconductor light-emitting device of the present disclosure. The epitaxial laminate in this embodiment is the same as that shown in FIG. 3 except for the design of the light-emitting structure 123. Referring to FIG. 7, in this embodiment, the light-emitting structure 123 includes a blocking interlayer 123C; specifically, the blocking interlayer 123C is located between one of the barrier layers 123A and one of the well layers 123B. In certain embodiments, the light-emitting structure 123 includes a plurality of layer units each containing a distinct one of the barrier layers 123A and a distinct one of the well layers 123B. At least two of the layer units each further include the blocking interlayer 123C, and in each of the at least two layer units, the blocking interlayer 123C is disposed between the barrier layer 123A and the well layer 123B. The blocking interlayer 123C has an energy band gap (E_{g6}), which is larger than the energy band gap (E_{g4}) of the second electron blocking layer 125b. In certain embodiments, the blocking interlayer 123C may be made of a material represented by Al_{c}Ga_{1-c}N, where 0.95≤c≤1. In some embodiments, the energy band gap (E_{g6}) of the blocking interlayer 123C is larger than the energy band gap (E_{g2}) of the barrier layers 123A. When the semiconductor light-emitting device is operating under a condition that an energy band is bent due to an applied bias voltage, and when the blocking interlayer 123C with the energy band gap (E_{g6}) that is 1.5 eV larger than the energy band gap (E_{g2}) of the barrier layers 123A, 123D is introduced into the semiconductor light-emitting device, potential barrierspike may be generated, thereby preventing overflow of carriers and increasing radiative recombination efficiency.

FIG. 8 shows an epitaxial laminate of an embodiment of the semiconductor light-emitting device of the present disclosure. The epitaxial laminate in this embodiment is the same as that shown in FIG. 7 except for the design of the light-emitting structure 123. Referring to FIG. 8, in this embodiment, in at least two layer units of the light-emitting structure 123, the well layer 123B of each of the at least two layer units includes a first layer 123B0 and a second layer 123B1. The first layer 123B0 is located between the blocking interlayer 123C and the second layer 123B1. That is to say, each of the at least two layer units sequentially includes the barrier layer 123A, the blocking interlayer 123C, the first layer 123B0, and the second layer 123B1. In other words, each of the well layers 123B that is located between corresponding two of the barrier layers 123A includes the first layer 123B0 and the second layer 123B1. The first layer 123B0 is mainly used for reducing a lattice difference between the blocking interlayer 123C and the second layer 123B1, and the second layer 123B1 is mainly used for emitting light. In this embodiment, the first layer 123B0 has a lattice constant that is between a lattice constant of the blocking interlayer 123C and a lattice constant of the second layer 123B1, thereby alleviating a problem caused by lattice-mismatch between different materials, so that the optoelectronic properties may be further improved. In certain embodiments, the first layer 123B0 has an energy band gap (E_{g7}), which is larger than the energy band gap (E_{g1}) of the well layers 123B, and which is smaller than the energy band gap (E_{g2}) of the barrier layers 123A, 123D. The first layer 123B0 may be made of a material represented by Al_{d}Ga_{1-d}N, where 0≤d≤0.5. Therefore, an emission wavelength of the light emitted by the light-emitting structure 123 may be well controlled. In addition, radiative recombination of holes and electrons in the second layer 123B1 may be enhanced. Thus, the radiative recombination efficiency of the light-emitting structure 123 may be improved simultaneously and the lumen depreciation effect of the semiconductor light-emitting device due to a plenty of interfacial defects may be avoided.

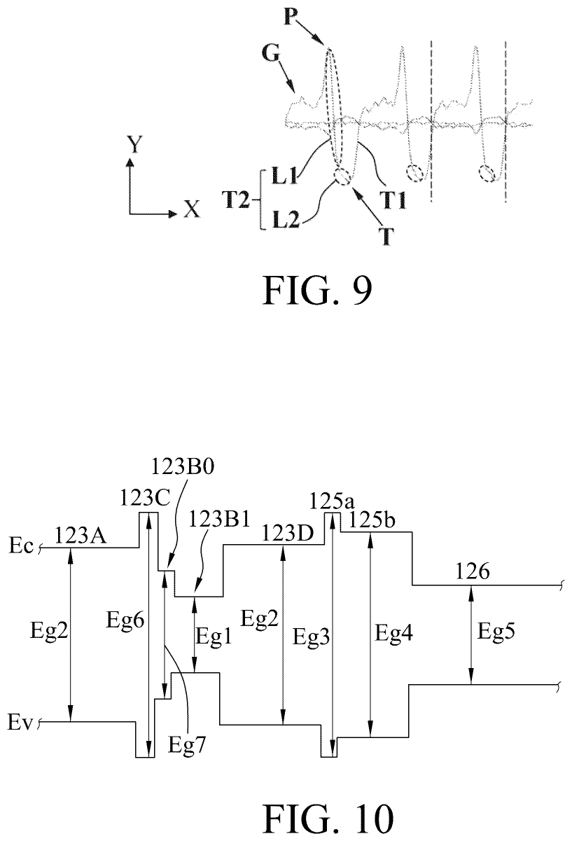

FIG. 9 shows an EDX spectrum of the light-emitting structure 123 shown in FIG. 8, which specifically shows a profile of the Al content. In FIG. 9, the x-axis represents a thickness of each layer, and the y-axis represents concentration intensity. The profile includes a plurality of groups each including a platform (G), a crest area (P), and a trough area (T). The platform (G) indicates an area where the fluctuation is smaller than that in each of the crest area (P) and the trough area (T). The fluctuation may be caused either by noise during testing or by change of the Al content that is intentionally adjusted. The platform (G) has a certain width and has a concentration between a concentration of the crest area (P) and a concentration of the trough area (T). In some embodiments, the Al content in the platform (G) may be gradually changed, e.g., may be gradually increased in a direction from the trough area (T) to the crest area (P). In this embodiment, the platform (G) corresponds to the barrier layer 123A and has a largest thickness. The crest area (P) corresponds to the blocking interlayer 123C and has a smallest thickness. The trough area (T) corresponds to the well layer 123B and has a thickness between the thickness of the crest area (P) and the thickness of the platform (G). That is to say, full width at half maximum (FWHM) of the trough area (T) is larger than FWHM of the crest area (P). Furthermore, the trough area (T) has an unsymmetrical shape, which includes a line segment (T1) and a line segment (T2). The line segment (T1) is close to the platform (G) and has a relatively small slope, and the line segment (T2) is close to the crest area (P) and has a first portion (L1) and a second portion (L2). The first portion (L1) is connected to the crest area (P), and the second portion (L2) is connected to the first portion (L1) and the line segment (T1). In this embodiment, formation of the second portion (L2) may be accomplished by inserting the first layer 123B0 that has an middle energy band gap into the blocking interlayer 123C and the second layer 123B1, and that may be, for example, a GaN layer or a AlGaN layer with a low Al content, so as to form a buffer region. In an embodiment, the second portion (L2) forms a small step. The step may avoid a sudden change in Al content between the crest area (P) and the trough area (T), thereby reducing the lattice difference between the blocking interlayer 123C and the well layer 123B, and may well confine electrons and holes that flow into the light-emitting structure 123 in the second layer 123B1 to perform radiative illumination, thereby increasing the radiative recombination efficiency and maintaining the consistency of the emission wavelength of light.

FIG. 10 shows a relationship of the energy band gaps of an epitaxial laminate that has the light-emitting structure 123 shown in FIG. 8. It can be noted that the energy band gaps in the layer units satisfy a relationship of E_{g1}<E_{g7}<E_{g2}<E_{g6}. Furthermore, in order to alleviate lattice-mismatch between the well layers 123B and the barrier layers 123A, a portion of each of the barrier layers 123A that is close to the adjacent well layer 123B may have an Al content that is gradually increased and then maintains at a particular level (i.e., remains unchanged).

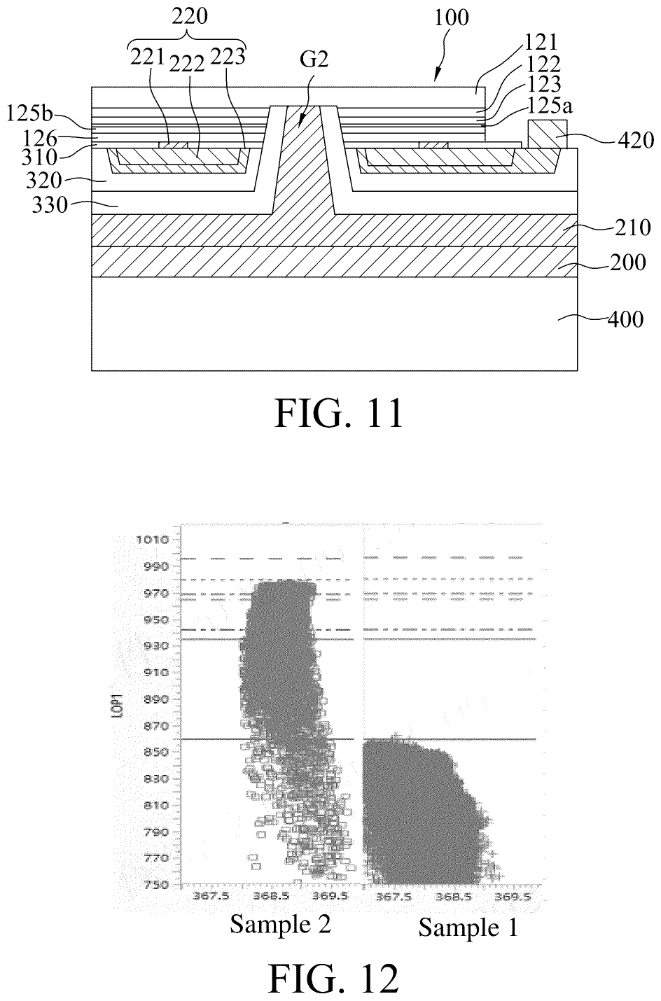

FIG. 11 shows a schematic view of an embodiment of a semiconductor light-emitting device according to the present disclosure. Referring to FIG. 11, the semiconductor light-emitting device has a vertical structure and includes a conductive substrate 400 and a semiconductor layer sequence 100 that is disposed on the conductive substrate 400. In some embodiments, the semiconductor light-emitting device may further include a connecting layer 200, e.g., a metal bonding layer or an insulating layer that is disposed between the conductive substrate 400 and the semiconductor layer sequence 100.

The semiconductor layer sequence 100 includes a sidewall and a first surface and a second surface opposite to the first surface. The first surface is a front side and the second surface is a rear side. The semiconductor layer sequence 100 includes the n-type semiconductor layer 121, the supper lattice layer 122, the light-emitting structure 123, the first electron blocking layer 125a, the second electron blocking layer 125b and the p-type hole injection layer 126, which are arranged sequentially in such order. The light-emitting structure 123 may have the structure shown in FIG. 2. The second surface of the semiconductor layer sequence 100 is formed with at least one recess G2 that at least penetrates the p-type hole injection layer 126, the second electron blocking layer 125b, the first electron blocking layer 125a, the light-emitting structure 123, the supper lattice layer 122, and a part of the n-type semiconductor layer 121. The semiconductor light-emitting device may further include a first electrical connection layer 210, a second electrical connection layer 220, and an insulating layer that has a first insulating layer 310, a second insulating layer 320, and a third insulating layer 330. The first electrical connection layer 210 is electrically connected to the p-type hole injection layer 126. The second electrical connection layer 220 includes a transparent conductive layer 221 that contacts the semiconductor layer sequence 100, a metal reflection layer 222, and a metal connection layer 223. The first electrical connection layer 210 has a protrusion that is formed in the recess G2, and is electrically connected to the n-type semiconductor layer 121. Through the second insulating layer 320 and the third insulating layer 330, the first electrical connection layer 210 and the second electrical connection layer 220 are electrically insulated from each other. The first electrical connection layer 210 and/or the second electrical connection layer 220 may include metal. The conductive substrate 400 serves as a first electrode and is electrically connected to the first electrical connection layer 210. The semiconductor light-emitting device further includes a second electrode 420 that is disposed on an upper surface of the second electrical connection layer 220. The first electrode and the second electrode 420 are used for external electrical connection. Furthermore, the first insulating layer 310 is disposed between the second electrical connection layer 220 and the semiconductor layer sequence 100, which is beneficial to improve the optoelectronic performance of the semiconductor light-emitting device.

Two chip samples (Samples 1 and 2) of a UV LED, each of which has a vertical structure shown in FIG. 11, has a chip size of 45 mil×45 mil and emits light with an emission wavelength mainly ranging from 365 nm to 370 nm, were prepared. A silicon substrate was used as the conductive substrate 400. Sample 1 had the epitaxial laminate shown in FIG. 7, in which the n-type semiconductor layer 121 was made of AlGaN, the p-type hole injection layer 126 was made of AlGaN, and the light-emitting structure 123 included five layer units each having an Al_{z3}Ga_{1-z3}N layer (z being 8 at %, and the Al_{z3}Ga_{1-z3}N layer having an thickness of 12 nm), an AlN layer (having an thickness of 0.7 nm), and an Inₓ₃Ga₁₋ₓ₃N layer (x3 being 0.5 at %, and the Inₓ₃Ga₁₋ₓ₃N layer having an thickness of 7 nm) (i.e., Al_{z3}Ga_{1-z3}N/AlN/Inₓ₃Ga₁₋ₓ₃N). Sample 2 had the epitaxial laminate shown in FIG. 8, in which the light-emitting structure 123 included five layer units each having an Al_{z3}Ga_{1-z3}N layer (z being 8 at %, and the Al_{z3}Ga_{1-z3}N layer having an thickness of 11 nm), an AlN layer (having an thickness of 0.7 nm), a GaN layer (having an thickness of 2 nm), and an Inₓ₃Ga₁₋ₓ₃N layer (x3 being 0.5 at %, and the Inₓ₃Ga₁₋ₓ₃N layer having an e thickness of 5 nm) (i.e., Al_{z3}Ga_{1-z3}N/AlN/GaN/Inₓ₃Ga₁₋ₓ₃N). The configurations of other layers of Sample 2 were the same as those of Sample 1.

FIG. 12 shows scatter plots of light output power (LOP) versus wavelength of Sample 1 and Sample 2 under a current of 500 mA. A circle-shaped carrier plate is used to support a substrate which is for growth of epitaxial laminates in an MOCVD process, and the epitaxial laminates grown on different positions of the carrier plate (i.e., different positions of the substrate) may have different epitaxial qualities. To eliminate the influence caused by growth on different positions, Sample 1 and Sample 2 were respectively obtained from different manufacturing batches at the same position on the carrier plate. According to FIG. 12, Samples 1 and 2 have light emission wavelengths ranging from 365 nm to 370 nm. The light output power (LOP) of Sample 2 is significantly larger than that of Sample 1, which indicates that Sample 2 has improved brightness.

Sample 1 and Sample 2 were subjected to an aging test under a temperature of 45° C. and a current of 3000 mA for 48 hours. The results show that the brightness of Sample 1 is decreased to 87.71% and the brightness of Sample 2 is decreased to 90.91%. That is to say, under a large current, lumen depreciation of Sample 2 was retarded.

Furthermore, a hot/cold factor of each of Sample 1 and Sample 2 was determined. The results are presented in Table 1. It is noted that brightness stability of Sample 2 at the high temperature working condition is significantly improved.

TABLE 1

| | Hot/cold (H/C) factor | | |
|---|---|---|---|
| | 25° C. | 95° C. | 120° C. |
| Sample 1 | 100% | 77% | 66% |
| Sample 2 | 100% | 86% | 80% |

An embodiment of a light-emitting apparatus according to the present disclosure includes a circuit substrate and a semiconductor light-emitting device disposed on the circuit substrate. The semiconductor light-emitting device may be any one of the aforesaid semiconductor light-emitting devices. The light-emitting apparatus exhibits a good anti-aging capability.

In summary, the first electron blocking layer 125a that contacts the last one barrier layer 123D has the energy band gap (E_{g3}) larger than the energy band gap (E_{g4}) of the second electron blocking layer 125b. The energy band gap (E_{g4}) of the second electron blocking layer 125b is larger than the energy band gap (E_{g2}) of the barrier layers 123A, 123D. In addition, the p-type hole injection layer 126 has the energy band gap (E_{g5}) that is smaller than the energy band gap (E_{g2}) of the barrier layers 123A, 123D. Through the aforesaid particular design in the energy band gaps, the p-type doping concentration of the light-emitting structure 123 may be well controlled, and thus, the anti-aging capability of the semiconductor light-emitting device may be effectively improved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor light-emitting device, comprising an n-type semiconductor layer, a light-emitting structure, a first electron blocking layer, a second electron blocking layer, and a p-type hole injection layer, which are sequentially stacked in such order,
wherein said light-emitting structure includes well layers and barrier layers that are stacked alternately, said first electron blocking layer contacts a last one of said barrier layers of said light-emitting structure and has an energy band gap (E_{g3}) that is larger than an energy band gap (E_{g4}) of said second electron blocking layer, the energy band gap (E_{g4}) of said second electron blocking layer is larger than an energy band gap (E_{g2}) of each of said barrier layers, and an energy band gap (E_{g5}) of said p-type hole injection layer is smaller than the energy band gap (E_{g2}) of each of said barrier layers.

2. The semiconductor light-emitting device as claimed in claim 1, wherein light emitted by said semiconductor light-emitting device has an emission wavelength ranging from 340 nm to 425 nm.

3. The semiconductor light-emitting device as claimed in claim 1, wherein said well layers have an energy band gap (E_{g1}), where E_{g3}>E_{g4}>E_{g2}>E_{g5}>E_{g1}.

4. The semiconductor light-emitting device as claimed in claim 1, wherein one of said well layers, which is nearest to said p-type hole injection layer, has a p-type doping concentration that is equal to or smaller than 5×10¹⁷ atoms/cm³.

5. The semiconductor light-emitting device as claimed in claim 1, wherein said second electron blocking layer has at least one V-shaped groove that extends into said light-emitting structure, said p-type hole injection layer filling said at least one V-shaped groove.

6. The semiconductor light-emitting device as claimed in claim 5, wherein said at least one V-shaped groove has an upper end that is located at a top surface of said second electron blocking layer and a lower end that is located in said light-emitting structure.

7. The semiconductor light-emitting device as claimed in claim 1, wherein except for said last one of said barrier layers, said barrier layers each has a p-type doping concentration that is equal to or smaller than 1×10¹⁷ atoms/cm³.

8. The semiconductor light-emitting device as claimed in claim 1, wherein said first electron blocking layer has a p-type doping concentration that is equal to or smaller than 1×10¹⁸ atoms/cm³.

9. The semiconductor light-emitting device as claimed in claim 1, wherein said second electron blocking layer has a p-type doping concentration that is equal to or smaller than 5×10¹⁹ atoms/cm³.

10. The semiconductor light-emitting device as claimed in claim 1, wherein said p-type hole injection layer has a doping concentration that is equal to or smaller than 1×10²⁰ atoms/cm³.

11. The semiconductor light-emitting device as claimed in claim 1, wherein said first electron blocking layer has a thickness ranging from 0.5 nm to 15 nm.

12. The semiconductor light-emitting device as claimed in claim 1, wherein said light-emitting structure further includes a blocking interlayer that is located between one of said barrier layers and one of said well layers, and that contacts said one of said barrier layers, said blocking interlayer having an energy band gap (E_{g6}) that is larger than the energy band gap (E_{g4}) of said second electron blocking layer.

13. The semiconductor light-emitting device as claimed in claim 1, wherein a ratio of a thickness of said well layers to a thickness of said barrier layers ranges from 1:1.5 to 1:2.0.

14. A semiconductor light-emitting device, comprising an n-type semiconductor layer, a light-emitting structure, an electron blocking layer, and a p-type hole injection layer, which are stacked sequentially in such order, said light-emitting structure including well layers and a barrier layers that are alternatively stacked,
wherein an energy band gap of said electron blocking layer is larger than an energy band gap (E_{g2}) of each of said barrier layers, said electron blocking layer having at least one V-shaped groove that extends into said light-emitting structure, said p-type hole injection layer filling said at least one V-shaped groove, said p-type hole injection layer having an energy band gap (E_{g5}) that is smaller than the energy band gap (E_{g2}) of said barrier layers.

15. The semiconductor light-emitting device as claimed in claim 14, wherein one of said well layers, which is nearest to said p-type hole injection layer, has a p-type doping concentration that is equal to or smaller than 5×10¹⁷ atoms/cm³.

16. The semiconductor light-emitting device as claimed in claim 14, wherein said at least one V-shaped groove has an upper end that is located at a top surface of said electron blocking layer and a lower end that is located in said light-emitting structure.

17. The semiconductor light-emitting device as claimed in claim 14, wherein said at least one V-shaped groove has a depth that is equal to or smaller than 120 nm.

18. The semiconductor light-emitting device as claimed in claim 14, wherein said p-type hole injection layer has a doping concentration that is equal to or smaller than 1×10²⁰ atoms/cm³.

19. The semiconductor light-emitting device as claimed in claim 14, wherein a last one of said barrier layers, which is adjacent to said electron blocking layer, has a p-type doping concentration that is equal to or smaller than 5×10¹⁷ atoms/cm³.

20. A light-emitting apparatus, comprising said semiconductor light-emitting device as claimed in claim 1.
